(19) United States
(12) Patent Application Publication
(10) Pub. No.: US 2025/0294939 A1
(43) Pub. Date: Sep. 18, 2025

(54) DISPLAY PANEL

(71) Applicant: PlayNitride Display Co., Ltd., MiaoLi County (TW)

(72) Inventor: Yu-Yun Lo, MiaoLi County (TW)

(73) Assignee: PlayNitride Display Co., Ltd., MiaoLi County (TW)

(21) Appl. No.: 18/650,099

(22) Filed: Apr. 30, 2024

(30) Foreign Application Priority Data
Mar. 18, 2024 (TW) 113109887

(51) Int. Cl. H01L 27/15

(52) U.S. Cl. CPC H10H 29/142

(57) ABSTRACT

A display panel including a circuit substrate, multiple bonding patterns, and multiple micro light emitting devices is provided. The bonding patterns are disposed on a substrate surface of the circuit substrate, and each has a first sidewall surface. The micro light emitting devices are respectively bonded to the circuit substrate through the bonding patterns, and each has a second sidewall surface. There is a step difference between the first sidewall surface and the second sidewall surface in any direction parallel to the substrate surface.

### CROSS-REFERENCE TO RELATED APPLICATION

This application claims the priority benefit of Taiwan patent application no. 113109887, filed on Mar. 18, 2024. The entirety of the above-mentioned patent application is hereby incorporated by reference herein and made a part of this specification.

### BACKGROUND

### Technical Field

The disclosure relates to a display panel, and in particular to a display panel having micro light emitting devices.

### Description of Related Art

Mass transfer is the current mainstream technology for manufacturing micro light emitting diode (micro-LED) display panels. Among them, a process method was proposed in which the complete epitaxial layer is first bonded to a CMOS (Complementary Metal Oxide Semiconductor) backplane and then etched and isolated to produce micro-LEDs. This type of process will first create a metal layer for bonding (such as Au or AuSn) on the circuit substrate before the separation of microcrystals. When gas etching is used to perform the above-mentioned separation process, part of the metal will react with the etching gas to form gas compounds and be taken away. However, due to the limitation of saturated vapor pressure, some of the removed metal may not be completely vaporized and remains in solid form on the side walls of the separated microcrystals, resulting in short circuit failure of the microcrystals or other structural defects.

### SUMMARY

The disclosure provides a display panel with a proper manufacturing process yield.

The display panel of the disclosure includes a circuit substrate, multiple bonding patterns, and multiple micro light emitting devices. The bonding patterns are disposed on a substrate surface of the circuit substrate, and each has a first sidewall surface. The micro light emitting devices are respectively bonded to the circuit substrate through the bonding patterns, and each has a second sidewall surface. The first sidewall surface and the second sidewall surface have a step difference in any direction parallel to the substrate surface.

Based on the above, in the display panel according to an embodiment of the disclosure, the micro light emitting device is bonded to the substrate surface of the circuit substrate through the bonding pattern. In any direction parallel to the substrate surface, there is the step difference between the first sidewall surface of the bonding pattern and the second sidewall surface of the micro light emitting device. The formation of the structural feature is due to covering of the micro light emitting devices during the etching process of the bonding pattern, thereby preventing the residues of the bonding pattern from affecting the micro light emitting devices. That is to say, the disclosure provides protection for the micro light emitting devices during the etching process, which can significantly reduce the risk of damage to the micro light emitting devices and help improve a process yield for separating complete epitaxial layers on the display panel.

### BRIEF DESCRIPTION OF THE DRAWINGS

FIG. 1 is a schematic cross-sectional view of a display panel according to the first embodiment of the disclosure.

FIGS. 2A to 2E are schematic cross-sectional views of a manufacturing process of the display panel of FIG. 1.

FIG. 3 is a schematic cross-sectional view of a display panel according to the second embodiment of the disclosure.

FIGS. 4A to 4B are schematic cross-sectional views of part of the manufacturing process of the display panel of FIG. 3.

FIG. 5 is a schematic cross-sectional view of a display panel according to the third embodiment of the disclosure.

FIG. 6 is a schematic cross-sectional view of a display panel according to the fourth embodiment of the disclosure.

FIG. 7 is a schematic cross-sectional view of a display panel according to the fifth embodiment of the disclosure.

### DESCRIPTION OF THE EMBODIMENTS

In the accompanying drawings, thicknesses of layers, films, panels, regions and so on are exaggerated for clarity. It should be understood that when an element such as a layer, a film, an area, or a substrate is described as being “on” another element or “connected to” another element, the element may be directly on another element or connected to another element, or there may be other elements interposed therebetween. In contrast, when an element is described as being “directly on another element” or “directly connected to” another element, there is no other element therebetween. Herein, “connect” used in the specification may refer to physical and/or electrical connection. Furthermore, “electrically connect” or “coupled to” may mean that there are other elements interposed between two elements.

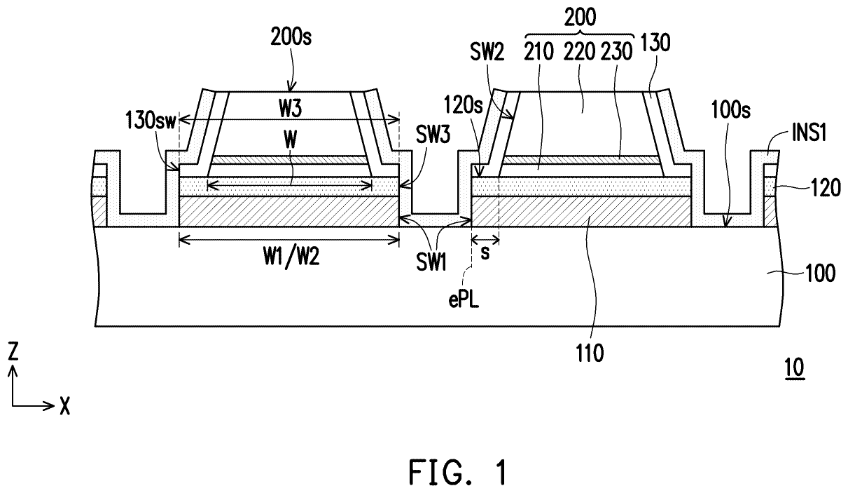

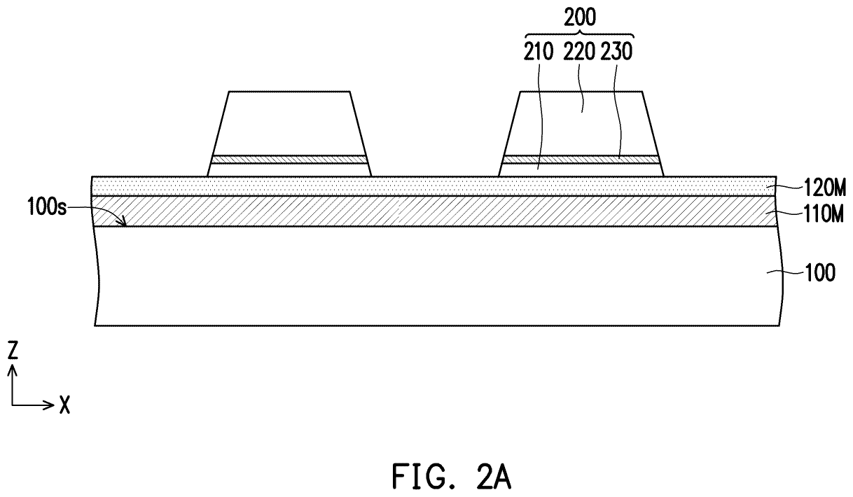

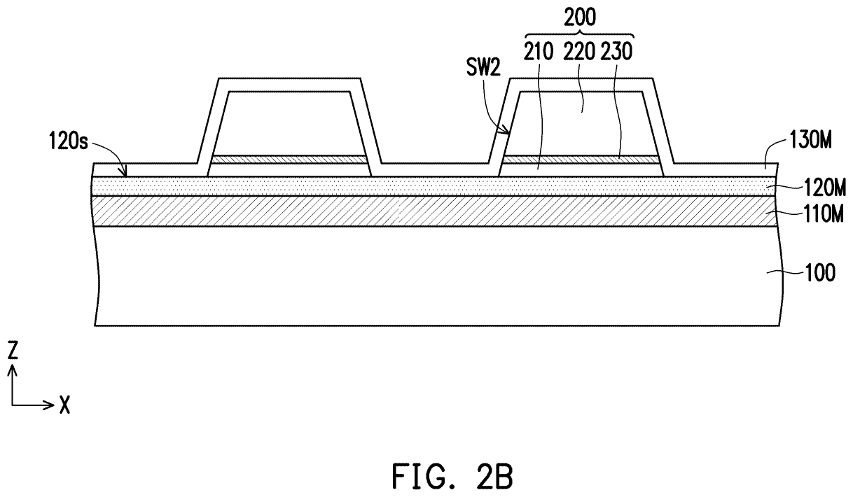

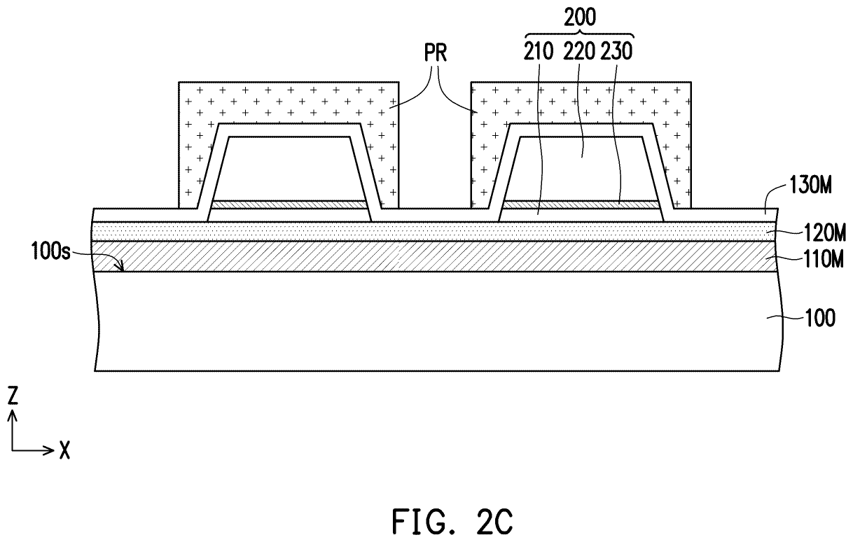

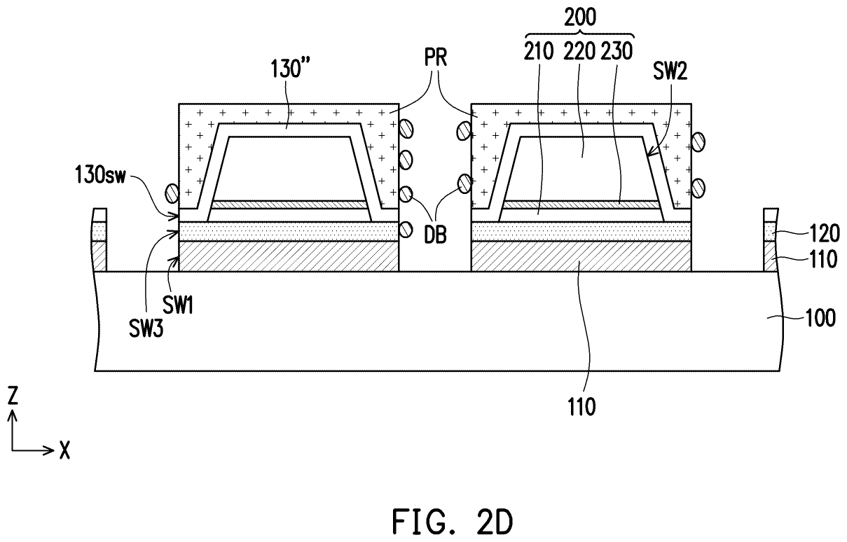

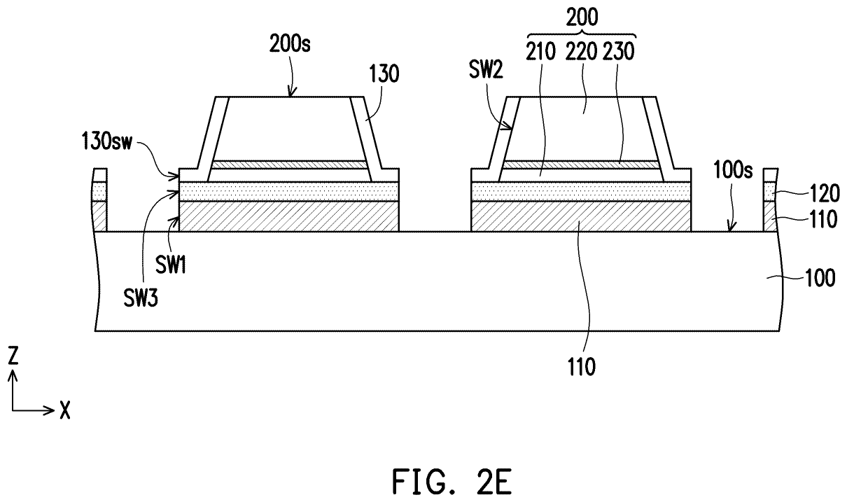

FIG. 1 is a schematic cross-sectional view of a display panel according to the first embodiment of the disclosure. FIGS. 2A to 2E are schematic cross-sectional views of a manufacturing process of the display panel of FIG. 1. Referring to FIG. 1, a display panel 10 includes a circuit substrate 100, multiple bonding patterns 110, and multiple micro light emitting devices 200. The circuit substrate 100 is, for example, a complementary metal oxide semiconductor (CMOS) backplane, but is not limited thereto. The bonding patterns 110 are disposed on a substrate surface 100s of the circuit substrate 100. The micro light emitting devices 200 are respectively bonded to the circuit substrate 100 through the bonding patterns 110. A material of the bonding pattern 110 is, for example, Au or AuSn, but is not limited thereto.

In this embodiment, the micro light emitting device 200 may include a first-type semiconductor layer 210, an active layer 230, and a second-type semiconductor layer 220 sequentially stacked in a direction (e.g., a direction Z) away from the circuit substrate 100. More specifically, the micro light emitting device 200 of this embodiment is, for example, a vertical type micro light emitting device, but is not limited thereto. The first-type semiconductor layer 210 and the second-type semiconductor layer 220 may be respectively a P-type semiconductor (such as p-GaN) and an N-type semiconductor (such as n-GaN). The active layer 230 may be a multiple quantum well (MQW) structure, but is not limited thereto.

An ohmic contact layer 120 may be disposed between each of the micro light emitting devices 200 and the corresponding bonding pattern 110. The material of the ohmic contact layer 120 may be metal oxide (e.g., indium tin oxide), but is not limited thereto. In other embodiments, the material of the ohmic contact layer 120 may also include metal or alloy (e.g. Ni/Ag). Therefore, in this embodiment, the ohmic contact layer 120 has a high reflectivity for light and may also serve as a light reflection layer of a display panel 10C.

It is particularly noted that the display panel 10 may also selectively cover a sidewall surface SW2 of each of the micro light emitting devices 200 with an etching protection layer 130. In this embodiment, the etching protection layer 130 may completely cover the sidewall surface SW2 of the micro light emitting device 200 and extend from the sidewall surface SW2 to cover a surface 120s of the ohmic contact layer 120 facing away from the circuit substrate 100. That is, the sidewall surface SW2 of the micro light emitting device 200 only contacts the etching protection layer 130.

Although the etching protection layer 130 covers the sidewall surface SW2 of the micro light emitting device 200, a surface 200s of the micro light emitting device 200 facing away from the circuit substrate 100 is exposed. It should be noted that the display panel 10 may also include a common electrode layer (not shown) covering and contacting the respective surfaces 200s of the micro light emitting devices 200 to electrically connect the second-type semiconductor layers 220 of each of the micro light emitting devices 200. In order to prevent the common electrode layer from further contacting the bonding pattern 110 and causing an electrical short circuit in the micro light emitting device 200, the display panel 10 may further include an insulation layer INS1 covering the etching protection layer 130, a sidewall surface SW3 of the ohmic contact layer 120, and a sidewall surface SW1 of the bonding pattern 110. That is, the etching protection layer 130 is located between the insulation layer INS1 and the sidewall surface SW2. It is particularly noted that in this embodiment, the ohmic contact layer 120 contacts the etching protection layer 130 and the insulation layer INS1 at the same time.

In another embodiment not shown, the insulation layer INS1 may also be implemented as a planarization layer between the micro light emitting devices 200, and the common electrode layer extends on the planarization layer. That is to say, the planarization layer is filled between the micro light emitting devices 200 to isolate the common electrode layer and the ohmic contact layer 120 from the bonding pattern 110. In this way, the common electrode layer may be implemented as a planar film layer based on the planarization layer.

The manufacturing process of the display panel 10 is exemplarily described below.

Referring to FIG. 2A, first, an epitaxial layer preformed on an epitaxial substrate (not shown) is bonded to the circuit substrate 100. The epitaxial substrate includes, for example, a semiconductor wafer or a sapphire substrate. After the bonding is completed, a patterning process is performed on the epitaxial layer on the circuit substrate 100 to form the micro light emitting devices 200. The patterning process uses photolithography technology, for example, but is not limited thereto.

Before bonding the epitaxial layer, a bounding material layer 110M and an ohmic contact material layer 120M are formed on the substrate surface 100s of the circuit substrate 100. In this embodiment, the ohmic contact material layer 120M is made of, for example, indium tin oxide (ITO). The epitaxial layer is made of, for example, gallium nitride (GaN). During the patterning process of the epitaxial layer, due to different etching selectivity ratios of etching gas or etching liquid for ITO and GaN, the ohmic contact material layer 120M made of ITO may be used as an etching stop layer. The material of the bonding material layer 110M includes, for example, gold (Au), tin (Sn), indium (In), copper (Cu), silver (Ag), or alloys of the above materials. Before the patterning process, the ohmic contact material layer 120M may also be formed on the entire epitaxial layer of the epitaxial substrate, and be bonded to the bonding material layer 110M during the bonding process.

Next, referring to FIG. 2B, an etching protection material layer 130M is optionally formed to cover the micro light emitting devices 200 and the surface 120s of the ohmic contact material layer 120M. The material of the etching protection material layer 130M includes, for example, silicon dioxide (SiO₂) or aluminum oxide (Al₂O₃), but is not limited thereto. Referring to FIG. 2C, after forming the etching protection material layer 130M, multiple photoresist patterns PR are formed. In the direction Z, the photoresist patterns PR respectively overlap with the micro light emitting devices 200. In other embodiments, the photoresist patterns PR may also be replaced by multiple mask patterns made of the silicon dioxide or other suitable materials, which is not limited by the disclosure.

Specifically, in this embodiment, an orthographic projection of the micro light emitting devices 200 on the substrate surface 100s may be located within the orthographic projection of the photoresist patterns PR on the substrate surface 100s. That is, the micro light emitting devices 200 completely overlap the photoresist patterns PR. In response to an alignment accuracy of the photoresist pattern PR during the manufacturing process being high enough, the manufacture of the etching protection material layer 130M may be omitted, and the micro light emitting device 200 may be directly covered with the photoresist pattern PR.

Referring to FIG. 2D, after completing the manufacture of the photoresist pattern PR, the bonding material layer 110M and the ohmic contact material layer 120M are patterned to form multiple etching protection layers 130″, the bonding patterns 110, and the ohmic contact layers 120. During the patterning process, part of the metal of the bonding material layer 110M may be vaporized and react with etching gas. Since the presence of gas is affected by saturated vapor pressure, part of the metal taken away is not completely vaporized and remains in a solid form (such as metal debris DB) on the surface of the photoresist pattern PR.

From another point of view, since the micro light emitting device 200 is covered by the etching protection layer 130″ and the photoresist pattern PR, the metal debris DB generated during the patterning process of the bonding material layer 110M and the ohmic contact material layer 120M does not adhere to the sidewall surface SW2 of the micro light emitting device 200. In this way, during the process of forming the bonding pattern 110 and the ohmic contact layer 120, the metal debris DB generated thereby may be prevented from adhering to the sidewall surface SW2 of the micro light emitting device 200 to cause electrical short circuit and failure.

The etching protection layer 130″, the ohmic contact layer 120, and the bonding pattern 110 formed after patterning have respectively a sidewall surface 130sw, a sidewall surface SW3, and the sidewall surface SW1. In this embodiment, the sidewall surface 130sw of the etching protection layer 130″ may be aligned with the overlapping sidewall surface SW3 of the ohmic contact layer 120 and the sidewall surface SW1 of the bonding pattern 110, but is not limited thereto.

As shown in FIG. 2E, the photoresist pattern PR is removed and a cleaning process is performed to remove the metal debris DB. After the metal debris DB is removed, the insulation layer INS1 is formed to cover the sidewall surface SW2 of the micro light emitting device 200, the sidewall surface 130sw of the etching protection layer 130, the sidewall surface SW3 of the ohmic contact layer 120, the sidewall surface SW1 of the bonding pattern 110, and part of the substrate surface 100s of the circuit substrate 100 as shown in FIG. 1. The material of the insulation layer INS1 includes, for example, the silicon dioxide (SiO₂) or the aluminum oxide (Al₂O₃).

In particular, after removing the photoresist pattern PR, a removal step of part of the etching protection layer 130″ may be performed to form the etching protection layer 130 exposing the surface 200s of the micro light emitting device 200 (as shown in FIG. 2E). However, the disclosure is not limited thereto. In another variant embodiment, the removal step of part of the etching protection layer 130″ may be integrated into the patterning process of the insulation layer INS1. More specifically, the removal of part of the insulation layer INS1 and the removal of part of the etching protection layer 130″ may be completed in the same etching step.

Although not shown, after the insulation layer INS1 is formed, the common electrode layer may be formed to electrically contact the second-type semiconductor layer 220 of each of the micro light emitting devices 200. In addition, an encapsulation layer for covering the micro light emitting devices 200 may also be formed to improve the resistance of the display panel 10 to the operating environment. At this point, the manufacture of the display panel 10 of this embodiment is completed.

Specifically, in the patterning process of FIG. 2C and FIG. 2D, since a width of the photoresist pattern PR in any direction parallel to the substrate surface 100s (for example, the direction Z) is greater than an element width of the micro light emitting device 200 covered thereby in the any direction parallel to the substrate surface 100s. Therefore, a width W1, a width W2, and a width W3 that the bonding pattern 110, the ohmic contact layer 120, and the etching protection layer 130 formed after etching respectively have in any direction parallel to the substrate surface 100s are all larger than an element width W of the micro light emitting device 200.

From another point of view, in any direction parallel to the substrate surface 100s, the sidewall surface SW1 of the bonding pattern 110 and the sidewall surface SW2 of the micro light emitting device 200 have a spacing s (i.e., a step difference). In other words, the sidewall surface SW2 of the micro light emitting device 200 is retracted compared to the side wall surface SW1 of the bonding pattern 110. Such structural features are attributed to the fact that the micro light emitting device 200 is covered by the photoresist pattern PR (as shown in FIG. 2C) during the etching process of the bonding pattern 110. Therefore, during the process of forming the bonding pattern 110 and the ohmic contact layer 120, it is possible to avoid the generated metal debris DB from adhering to the sidewall surface SW2 of the micro light emitting device 200 to cause the electrical short circuit and failure. In other words, the display panel 10 with the above structural features can have proper process yield.

In this embodiment, the width W1 of the bonding pattern 110, the width W2 of the ohmic contact layer 120, and the width W3 of the etching protection layer 130 may be substantially equal to each other, but are not limited thereto. The bonding pattern 110, the ohmic contact layer 120, and the etching protection layer 130 may be coplanarly cut off at a cutoff plane ePL. That is, the sidewall surface SW1 of the bonding pattern 110, the sidewall surface SW3 of the ohmic contact layer 120, and the sidewall surface 130sw of the etching protection layer 130 may be aligned with each other and form the cutoff plane ePL.

In the following, other embodiments are provided to explain the disclosure in detail. The same members are labeled with the same reference numerals, and description of the same technical content is omitted. For the omitted parts, please refer to the above embodiments, which are not repeated herein.

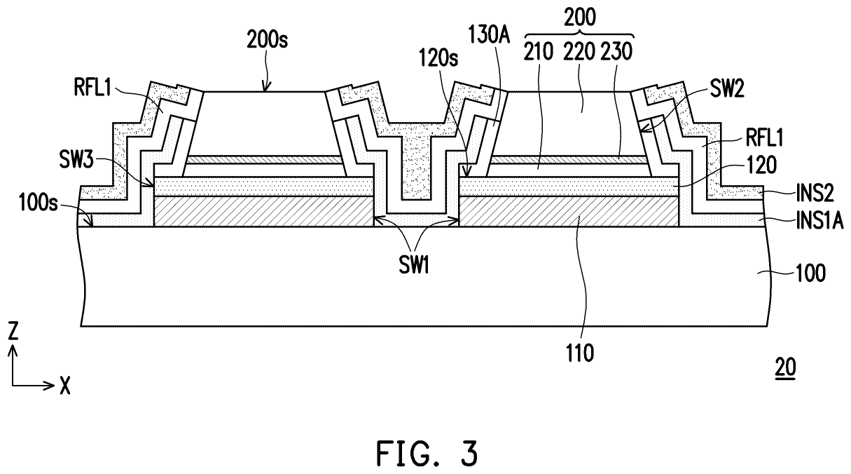

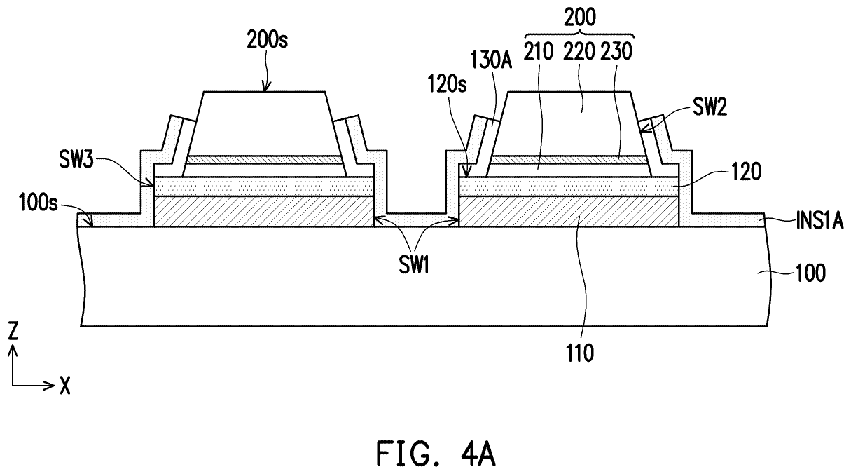

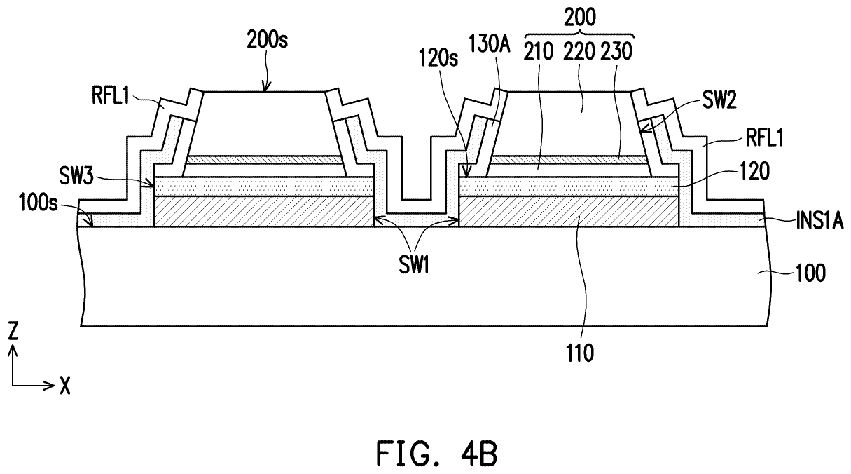

FIG. 3 is a schematic cross-sectional view of a display panel according to the second embodiment of the disclosure. FIGS. 4A to 4B are schematic cross-sectional views of part of the manufacturing process of the display panel of FIG. 3. Referring to FIG. 3, compared with the display panel 10 of FIG. 1, the display panel 20 of this embodiment may also optionally include a light reflection layer RFL1. Specifically, in this embodiment, an etching protection layer 130A and an insulation layer INS1A only cover a part of the sidewall surface SW2 of the micro light emitting device 200, while another part of the sidewall surface SW2 is covered by the light reflection layer RFL1. In other words, the sidewall surface SW2 of the micro light emitting device 200 are completely covered by the light reflection layer RFL1 and the etching protection layer 130A.

It is particularly noted that the light reflection layer RFL1 also extends from the sidewall surface SW2 of the micro light emitting device 200 to cover the sidewall surface SW3 of the ohmic contact layer 120 and the sidewall surface SW1 of the bonding pattern 110. Through the arrangement of the light reflection layer RFL1, a light extraction efficiency of the micro light emitting device 200 can be effectively improved. In order to protect the light reflection layer RFL1, in the display panel 20, a side of the light reflection layer RFL1 facing away from the micro light emitting device 200 may be covered with another insulation layer INS2. That is, the light reflection layer RFL1 is sandwiched between the insulation layer INS1A and the insulation layer INS2.

Since the manufacturing process of the display panel 20 of this embodiment before forming the insulation layer INS1A is similar to the manufacturing process of the display panel 10 of FIG. 1, for a detailed description, please refer to the relevant paragraphs of the above embodiment, which is not repeated herein. The following describes only the manufacturing process differences between the display panel 20 and the display panel 10 in FIG. 1.

Referring to FIG. 4A, after the patterning process of the insulation layer INS1A and the etching protection layer 130A is completed, in addition to the surface 200s of the micro light emitting device 200, part of the sidewall surface SW2 thereof is also exposed. Next, the light reflection layer RFL1 is formed on the sidewall surface SW2 of the micro light emitting device 200, as shown in FIG. 4B. It is particularly noted that the light reflection layer RFL1 directly contacts part of the sidewall surface SW2 that is not covered by the etching protection layer 130A, and extends to cover the insulation layer INS1A. The material of the light reflection layer RFL1 includes, for example, silver (Ag) or aluminum (Al), but is not limited thereto.

After completing the manufacture of the light reflection layer RFL1, the insulation layer INS2 covering the light reflection layer RFL1 and exposing the surface 200s of the micro light emitting device 200 is formed, as shown in FIG. 3. The material of the insulation layer INS2 includes, for example, the silicon dioxide (SiO₂) or the aluminum oxide (Al₂O₃). Since the process of forming the insulation layer INS2 of the display panel 20 of this embodiment is similar to the process of forming the insulation layer INS1 of the display panel 10 of FIG. 1, for a detailed description, please refer to the relevant paragraphs of the above embodiment, which is not repeated herein.

At this point, the manufacture of the display panel 20 of this embodiment is completed. In this embodiment, the sidewall surface SW2 of the micro light emitting device 200 is covered with the light reflection layer RFL1. The light reflection layer RFL1 extends from the sidewall surface SW2 to cover the sidewall surface SW1 of the bonding pattern 110. The light reflection layer RFL1 may electrically contact the second-type semiconductor layer 220 of the micro light emitting device 200 through the part of the sidewall surface SW2 exposed by the insulation layer INS1A and the etching protection layer 130A, and is electrically insulated from the first-type semiconductor layer 210 and the active layer 230.

From another point of view, in this embodiment, the sidewall surface SW2 of the micro light emitting device 200 may be covered with three insulating layers, which are respectively the etching protection layer 130A, the insulation layer INS1A, and the insulation layer INS2. A coverage area of the etching protection layer 130A (which only extends to cover the surface 120s of the ohmic contact layer 120) is different from the coverage areas of the insulation layer INS1A and the insulation layer INS2.

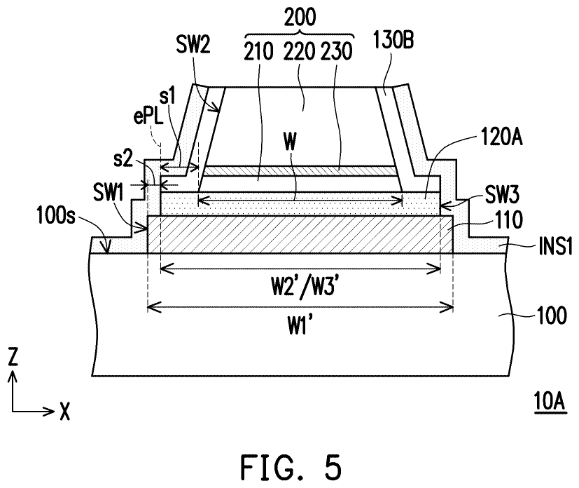

FIG. 5 is a schematic cross-sectional view of a display panel according to the third embodiment of the disclosure. Referring to FIG. 5, the difference between a display panel 10A of this embodiment and the display panel 10 of FIG. 1 lies in a size relationship between the ohmic contact layer and the bonding pattern. Specifically, in this embodiment, a width W2′ of an ohmic contact layer 120A in the direction X (or any direction parallel to the substrate surface 100s) is equal to a width W3′ of an etching protection layer 130B in the direction X, and is less than a width W1′ of the bonding pattern 110 in the direction X.

The difference from the previous embodiment is that the ohmic contact layer 120A and the etching protection layer 130B are coplanarly cut off at the cutoff plane ePL, but the cutoff plane ePL is not coplanar with the sidewall surface SW1 of the bonding pattern 110. Specifically, the cutoff plane ePL is located between the sidewall surface SW1 of the bonding pattern 110 and the sidewall surface SW2 of the micro light emitting device 200. In any direction parallel to the substrate surface 100s (for example, the direction X), there is a spacing s1 between the sidewall surface SW2 of the micro light emitting device 200 and the cutoff plane ePL. There is a spacing s2 between the sidewall surface SW1 of the bonding pattern 110 and the cutoff plane ePL (or the sidewall surface SW3 of the ohmic contact layer 120A). That is, there is a step difference between each of the sidewall surface SW2 and the sidewall surface SW1 and the cutoff plane ePL.

More specifically, the cutoff plane ePL of the ohmic contact layer 120A and the etching protection layer 130B is retracted compared to the sidewall surface SW1 of the bonding pattern 110. The reason for the structural feature is that in addition to using the photoresist pattern PR (as shown in FIG. 2C) to cover the micro light emitting device 200 during the etching process of the bonding pattern 110, the etching selectivity ratio of the selected etching gas or etching liquid to the etching protection material layer and the ohmic contact layer is greater than the bounding material layer is also one of the reasons. In addition, since the thickness of the etching protection layer 130B is usually small, the difference in time between the etching protection layer 130B and the ohmic contact layer 120A being exposed to the process environment is extremely small. Therefore, in the embodiment of FIG. 1 or FIG. 5, the etching protection layer 130B and the ohmic contact layer 120A are substantially aligned.

Since the manufacturing method of the display panel 10A of this embodiment is similar to the manufacturing method of the display panel 10 of FIG. 1, for a detailed description, please refer to the relevant paragraphs of the above embodiment, which is not repeated herein. Specifically, in the embodiment of FIG. 5, the relationship between the widths of the bonding pattern 110, the ohmic contact layer 120A, and the micro light emitting device 200 (that is, the width W2′ and the width W3′ are less than the width W1′ and greater than the width W) may allow an entire surface of the film structures to be in a stepped shape, so that the insulation layer INS1 is less likely to break during a subsequent film formation process.

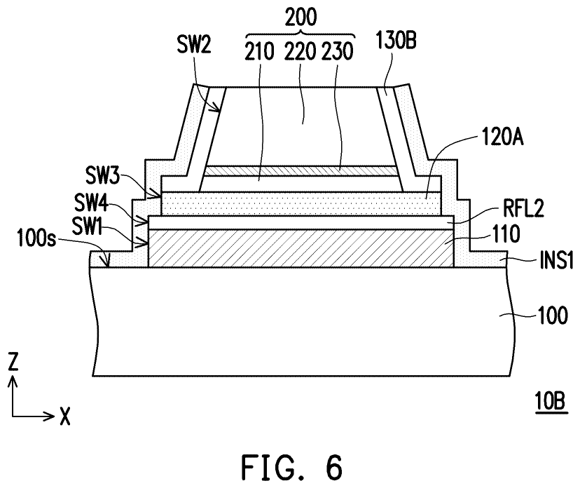

FIG. 6 is a schematic cross-sectional view of a display panel according to the fourth embodiment of the disclosure. Referring to FIG. 6, compared with the display panel 10A of FIG. 5, a display panel 10B of this embodiment may also optionally include a light reflection layer RFL2 disposed between the micro light emitting devices 200 and the bonding patterns 110 overlapping with each other. An arrangement of the light reflection layer RFL2 may effectively improve the light extraction efficiency of the micro light emitting device 200. More specifically, the light reflection layer RFL2 is located between the ohmic contact layer 120A and the bonding pattern 110. The material of the light reflection layer RFL2 includes, for example, the silver (Ag) or the aluminum (Al).

It is particularly important to note that in this embodiment, since the material of the light reflection layer RFL2 is also metal, during the etching process of the bonding pattern 110, the difference of the etching selectivity ratio of the etching gas or etching liquid to the bonding material layer and the light reflection material layer is small, and a requirement of the thickness of the light reflection material layer based on light reflection is not high. Therefore, a sidewall surface SW4 of the light reflection layer RFL2 formed after etching may be substantially aligned with the sidewall surface SW1 of the bonding pattern 110, but the disclosure is not limited thereto.

Since the remaining components and structural relationships of the display panel 10B are similar to the display panel 10A of FIG. 5, for a detailed description, please refer to the relevant paragraphs of the above embodiment, which is not repeated herein.

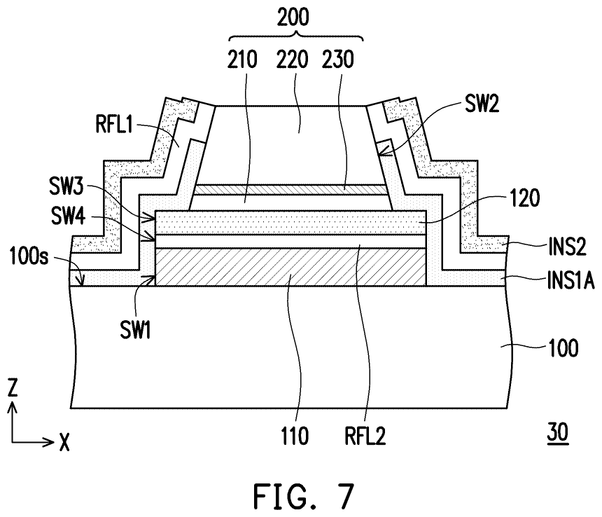

FIG. 7 is a schematic cross-sectional view of a display panel according to the fifth embodiment of the disclosure. Referring to FIG. 7, compared with the display panel 20 of FIG. 3, a display panel 30 of this embodiment may also optionally include the light reflection layer RFL2 disposed between the ohmic contact layer 120 and the bonding pattern 110. The material of the light reflection layer RFL2 and the light reflection layer RFL1 may be the same. In this embodiment, the additional light reflection layer RFL2 may reflect the light emitted by the active layer 230 or the light reflection layer RFL1 in a-Z direction, further improving the light extraction efficiency of the micro light emitting device 200.

It is particularly noted that the display panel 30 of this embodiment is not provided with the etching protection layer 130A in FIG. 3. Therefore, the sidewall surface SW2 of the micro light emitting device 200 is completely covered by the light reflection layer RFL1 and the insulation layer INS1A. That is to say, this embodiment does not have a structure in which the sidewall surface 130sw of the etching protection layer 130 is aligned with the sidewall surface SW3 of the ohmic contact layer 120 as shown in FIG. 1. However, depending on the manufacturing process conditions, this embodiment may also be implemented in such a manner that the etching protection layer 130A in FIG. 3 covers part or all of the sidewall surface SW2.

Since the remaining components and structural relationships of the display panel 30 are similar to the display panel 20 of FIG. 3, for a detailed description, please refer to the relevant paragraphs of the above embodiment, which is not repeated herein.

To sum up, in the display panel according to an embodiment of the disclosure, the micro light emitting device is bonded to the substrate surface of the circuit substrate through the bonding pattern. In any direction parallel to the substrate surface, there is the step difference between a first sidewall surface of the bonding pattern and a second sidewall surface of the micro light emitting device. The formation of the structural feature is due to the use of photoresist patterns to cover the micro light emitting devices during the etching process of the bonding pattern. Also because of the arrangement of the photoresist pattern, the risk of damage to the micro light emitting devices separated on the circuit substrate during the subsequent formation of the bonding pattern can be greatly reduced, which helps to improve the process yield of the display panel.

What is claimed is:

1. A display panel, comprising:
a circuit substrate;
a plurality of bonding patterns, disposed on a substrate surface of the circuit substrate, wherein each of the plurality of bonding patterns has a first sidewall surface; and
a plurality of micro light emitting devices, respectively bonded to the circuit substrate through the plurality of bonding patterns, wherein each of the plurality of micro light emitting devices has a second sidewall surface, and the first sidewall surface and the second sidewall surface has a step difference in any direction parallel to the substrate surface.

2. The display panel according to claim 1, wherein an ohmic contact layer is provided between each of the plurality of micro light emitting devices and corresponding one of the plurality of bonding patterns, and in the any direction parallel to the substrate surface, a first width of the ohmic contact layer is less than or equal to a second width of each of the plurality of bonding patterns.

3. The display panel according to claim 2, wherein the ohmic contact layer is cut off by a third sidewall surface, and the third sidewall surface is aligned with the first sidewall surface of the corresponding one of the plurality of bonding patterns.

4. The display panel according to claim 2, wherein the second sidewall surface of each of the plurality of micro light emitting devices is covered with an etching protection layer, and the etching protection layer extends from the second sidewall surface to cover the ohmic contact layer facing away from a surface of the circuit substrate.

5. The display panel according to claim 4, wherein a third width of the etching protection layer is less than or equal to the second width in the any direction parallel to the substrate surface.

6. The display panel according to claim 4, wherein the ohmic contact layer and the etching protection layer are coplanarly cut off at a cutoff plane.

7. The display panel according to claim 6, wherein in the any direction parallel to the substrate surface, the cutoff plane is located between the first sidewall surface and the second sidewall surface, and the first sidewall surface and the second side wall surface has respectively a step difference with the cutoff plane.

8. The display panel according to claim 6, wherein the cutoff plane is aligned with the first sidewall surface.

9. The display panel according to claim 1, wherein the second sidewall of each of the plurality of micro light emitting devices is covered with a first light reflection layer, and the first light reflection layer extends from the second sidewall to cover the first sidewall.

10. The display panel according to claim 9, wherein a second light reflection layer is further disposed between each of the plurality of micro light emitting devices and corresponding one of the plurality of bonding patterns.

11. The display panel according to claim 9, wherein each of the plurality of micro light emitting devices comprises a first-type semiconductor layer, an active layer, and a second-type semiconductor layer stacked in a direction away from the circuit substrate, and the first light reflection layer electrically contacts the second-type semiconductor layer, and is electrically insulated from the first-type semiconductor layer and the active layer.

12. The display panel according to claim 9, wherein a first insulation layer and a second insulation layer are respectively disposed on two opposite sides of the first light reflection layer on each of the plurality of micro light emitting devices.

13. The display panel according to claim 12, wherein the first insulation layer contacts the second sidewall surface, and the second sidewall surface is completely covered by the first light reflection layer and the first insulation layer.

14. The display panel according to claim 12, wherein the second sidewall surface of each of the plurality of micro light emitting devices is covered with an etching protection layer. the etching protection layer is located between the first insulation layer and the second side wall surface, and the second side wall surface is completely covered by the first light reflection layer and the etching protection layer.
